(19) United States
(12) Patent Application Publication
(10) Pub. No.: US 2019/0164933 A1
(43) Pub. Date: May 30, 2019

(54) FAN-OUT SEMICONDUCTOR PACKAGE

(71) Applicant: SAMSUNG ELECTRO-MECHANICS CO., LTD., Suwon-Si (KR)

(72) Inventor: Suk Ho LEE, Suwon-Si (KR)

(21) Appl. No.: 16/008,810

(22) Filed: Jun. 14, 2018

(30) Foreign Application Priority Data
Nov. 29, 2017 (KR) 10-2017-0161205

(51) Int. Cl. H01L 25/065; H01L 23/498; H01L 23/31; H01L 23/00

(52) U.S. Cl. CPC H01L 25/0655; H01L 23/49822; H01L 23/49827; H01L 2224/13017; H01L 23/49838; H01L 24/13; H01L 23/3128

(57) ABSTRACT

A fan-out semiconductor package includes: a frame including insulating layers, wiring layers, and connection via layers, and having a recess portion and a stopper layer disposed on a bottom surface of the recess portion; a semiconductor chip having connection pads and disposed in the recess portion so that an inactive surface is connected to the stopper layer; an encapsulant covering at least portions of the semiconductor chip and filling at least portions of the recess portion; and a connection member disposed on the frame and an active surface of the semiconductor chip and including a redistribution layer electrically connecting the wiring layers and the connection pads to each other. The connection pads of the semiconductor chip are electrically connected to the redistribution layer of the connection member through wire posts disposed on the connection pads of the semiconductor chip.

### CROSS-REFERENCE TO RELATED APPLICATION(S)

This application claims benefit of priority to Korean Patent Application No. 10-2017-0161205 filed on Nov. 29, 2017 in the Korean Intellectual Property Office, the disclosure of which is incorporated herein by reference in its entirety.

### TECHNICAL FIELD

The present disclosure relates to a semiconductor package, and more particularly, to a fan-out semiconductor package in which electrical connection structures may extend outwardly of a region in which a semiconductor chip is disposed.

### BACKGROUND

A significant recent trend in the development of technology related to semiconductor chips has been reductions in the size of semiconductor chips. Therefore, in the field of package technology, in accordance with a rapid increase in demand for small-sized semiconductor chips, or the like, the implementation of a semiconductor package, having a compact size while including a plurality of pins, has been demanded.

One type of semiconductor package technology suggested to satisfy the technical demand, described above, is a fan-out semiconductor package. Such a fan-out package has a compact size and may allow a plurality of pins to be implemented by redistributing connection terminals up to an external region that is out of a region in which a semiconductor chip is disposed.

Particularly, in a package used in a package-on-package (POP), a semiconductor package in which a recess portion (referred to as a blind recess portion), opened in only one surface of a frame, is formed in the frame and a redistribution structure is implemented on the other surface of the frame, instead of implementing a separate redistribution layer on a rear surface (for example, a surface on which connection pads do not exist or an inactive surface) of a semiconductor chip, may be used.

### SUMMARY

An aspect of the present disclosure may provide a fan-out semiconductor package in which a connection structure between a backside redistribution layer and a semiconductor chip is improved.

According to an aspect of the present disclosure, a fan-out semiconductor package may include: a frame including a plurality of insulating layers, a plurality of wiring layers disposed on the plurality of insulating layers, and a plurality of connection via layers penetrating through the plurality of insulating layers and electrically connecting the plurality of wiring layers to each other, and having a recess portion and a stopper layer disposed on a bottom surface of the recess portion; a semiconductor chip disposed in the recess portion and having connection pads, an active surface on which the connection pads are disposed, and an inactive surface opposing the active surface and disposed on the stopper layer; an encapsulant covering at least portions of the semiconductor chip and filling at least portions of the recess portion; and a connection member disposed on the frame and the active surface of the semiconductor chip and including a redistribution layer electrically connecting the plurality of wiring layers of the frame and the connection pads of the semiconductor chip to each other. The connection pads of the semiconductor chip may be electrically connected to the redistribution layer of the connection member through wire posts disposed on the connection pads of the semiconductor chip.

According to another aspect of the present disclosure, a fan-out semiconductor package may include: a frame including a plurality of insulating layers and having a recess portion penetrating a portion of the frame, at least one of the plurality of insulating layers not penetrated through by the recess portion; first semiconductor chip and second semiconductor chips and disposed in the recess portion, each of the first and second semiconductor chip having connection pads, an active surface on which the connection pads are disposed, and an inactive surface opposing the active surface and disposed on the at least one of the plurality of insulating layers not penetrated through by the recess portion; an encapsulant covering at least portions of the first and second semiconductor chips and filling at least portions of the recess portion; a connection member disposed on the frame and the active surfaces of the first and second semiconductor chip and including a redistribution layer; first wire posts disposed between the connection pads of the first semiconductor chip and the redistribution layer, and electrically connecting the connection pads of the first semiconductor chip and the redistribution layer to each other; and second wire posts disposed between the connection pads of the second semiconductor chip and the redistribution layer, and electrically connecting the connection pads of the second semiconductor chip and the redistribution layer to each other. Each of the first wire posts may include a body portion disposed on one of the connection pads of the first semiconductor chip, and a lead portion having a width less than that of the body portion thereof and disposed between the body portion thereof and the redistribution layer. Each of the second wire posts may include a body portion disposed on one of the connection pads of the second semiconductor chip, and a lead portion having a width less than that of the body portion thereof and disposed between the body portion thereof and the redistribution layer. A thickness of the first semiconductor chip may be greater than a thickness of the second semiconductor chip, and a height of the lead portion of each of the first wire posts may be less than a height of the lead portion of each of the second wire posts.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on an interposer substrate and is ultimately mounted on a mainboard of an electronic device;

FIG. 6 is a schematic cross-sectional view illustrating a case in which a fan-in semiconductor package is embedded in an interposer substrate and is ultimately mounted on a mainboard of an electronic device;

FIG. 7 is a schematic cross-sectional view illustrating a fan-out semiconductor package;

FIG. 8 is a schematic cross-sectional view illustrating a case in which a fan-out semiconductor package is mounted on a mainboard of an electronic device;

FIG. 9 is a side cross-sectional view illustrating a fan-out semiconductor package according to an exemplary embodiment in the present disclosure;

FIG. 10 is a plan view taken along line I-I′ of the fan-out semiconductor package of FIG. 9;

FIGS. 11A and 11B are cross-sectional views illustrating various types of wire posts that may be used in an exemplary embodiment in the present disclosure;

FIG. 12 is a cross-sectional view illustrating an example of an injection port of a wire bonding device;

FIGS. 13A through 13E are cross-sectional views illustrating main processes of forming a frame;

FIGS. 14A through 14E are cross-sectional views illustrating main processes of manufacturing a fan-out semiconductor package; and

FIG. 15 is a side cross-sectional view illustrating a fan-out semiconductor package according to an exemplary embodiment in the present disclosure.

### DETAILED DESCRIPTION

Hereinafter, exemplary embodiments in the present disclosure will be described with reference to the accompanying drawings. In the accompanying drawings, shapes, sizes, and the like, of components may be exaggerated or shortened for clarity.

The meaning of a “connection” of a component to another component in the description includes an indirect connection through an adhesive layer as well as a direct connection between two components. In addition, “electrically connected” conceptually includes a physical connection and a physical disconnection. In addition, an ordinal number such as “first”, “second”, or the like, is used to distinguish one component from another component, and does not limit a sequence, importance, and the like, of the corresponding components. In some cases, a first element may be referred to as a second element without departing from the scope of the claims set forth herein. Similarly, a second element may also be referred to as a first element.

The term an “exemplary embodiment” used herein does not refer to the same exemplary embodiment, and is provided to emphasize a particular feature or characteristic different from that of another exemplary embodiment. However, exemplary embodiments provided herein are considered to be able to be implemented by being combined in whole or in part one with another. For example, one element described in a particular exemplary embodiment, even if it is not described in another exemplary embodiment, may be understood as a description related to another exemplary embodiment, unless an opposite or contradictory description is provided therein.

Terms used herein are used only in order to describe an exemplary embodiment rather than limiting the present disclosure. For example, singular forms need to be interpreted as including plural forms unless interpreted otherwise in context.

Electronic Device

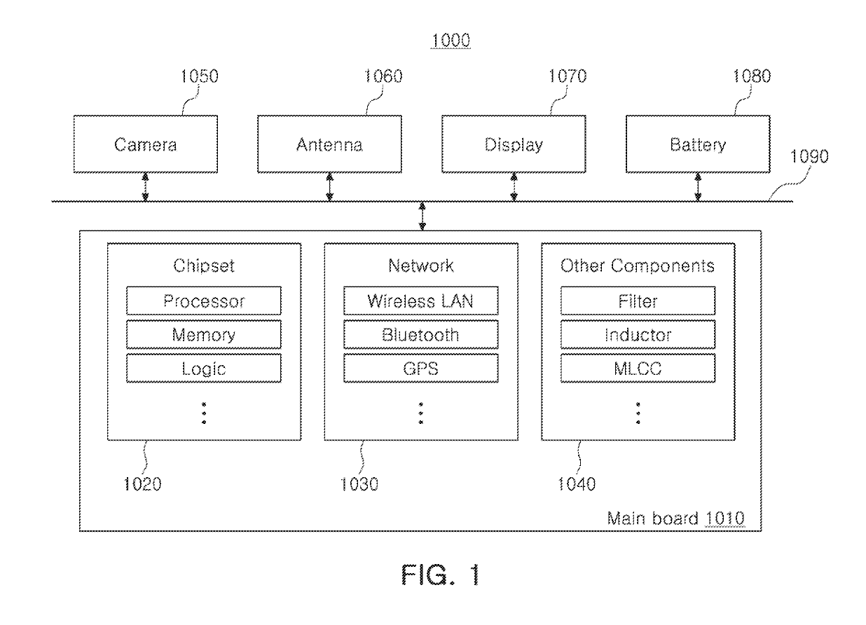

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

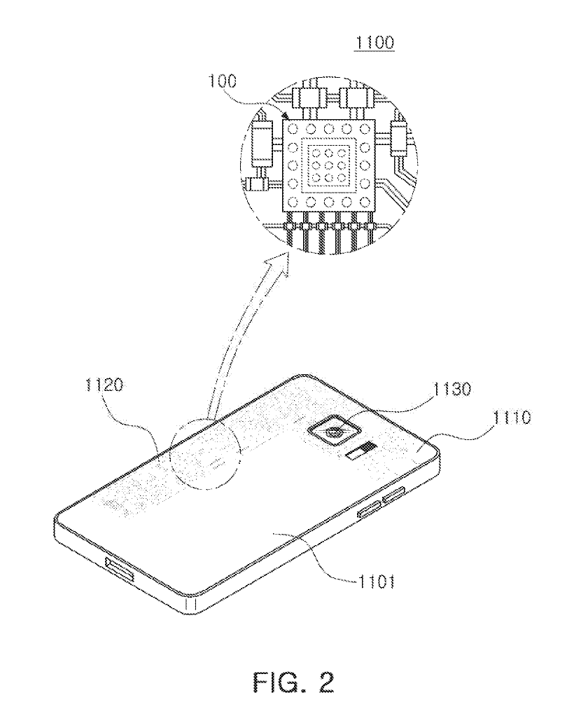

FIG. 2 is a schematic perspective view illustrating an example of an electronic device.

Referring to FIG. 2, a semiconductor package may be used for various purposes in the various electronic devices 1000 as described above. For example, a motherboard 1110 may be accommodated in a body 1101 of a smartphone 1100, and various electronic components 1120 may be physically or electrically connected to the motherboard 1110. In addition, other components that may or may not be physically or electrically connected to the mainboard 1010, such as a camera module 1130, may be accommodated in the body 1101. Some of the electronic components 1120 may be the chip related components, and the semiconductor package 100 may be, for example, an application processor among the chip related components, but is not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a semiconductor finished product in oneself, and may be damaged due to external physical or chemical impact. Therefore, the semiconductor chip is not used in oneself, and is packaged and is used in an electronic device, or the like, in a package state.

The reason why semiconductor packaging is required is that there is a difference in a circuit width between the semiconductor chip and a mainboard of the electronic device in terms of electrical connection. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the accompanying drawings.

Fan-in Semiconductor Package

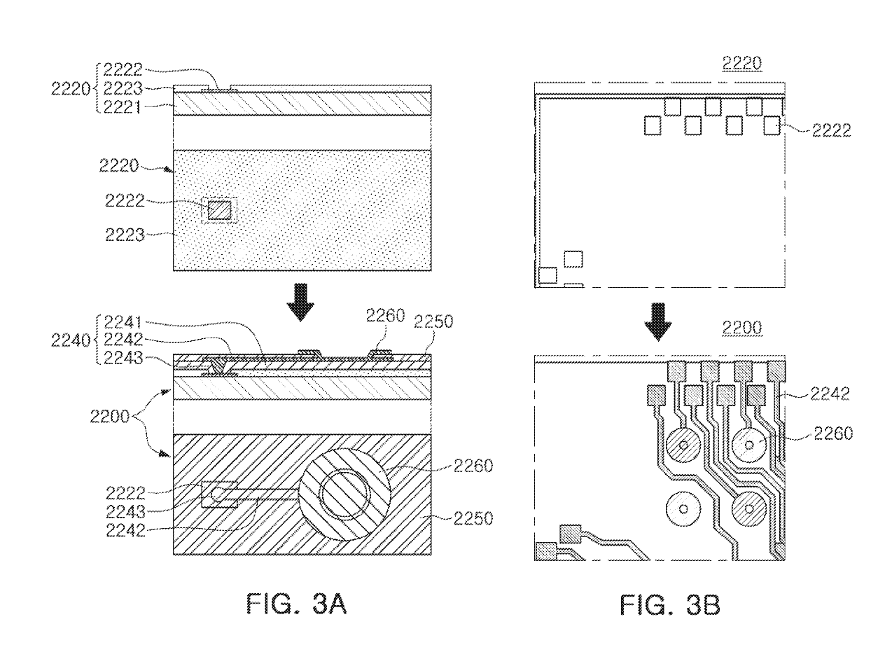

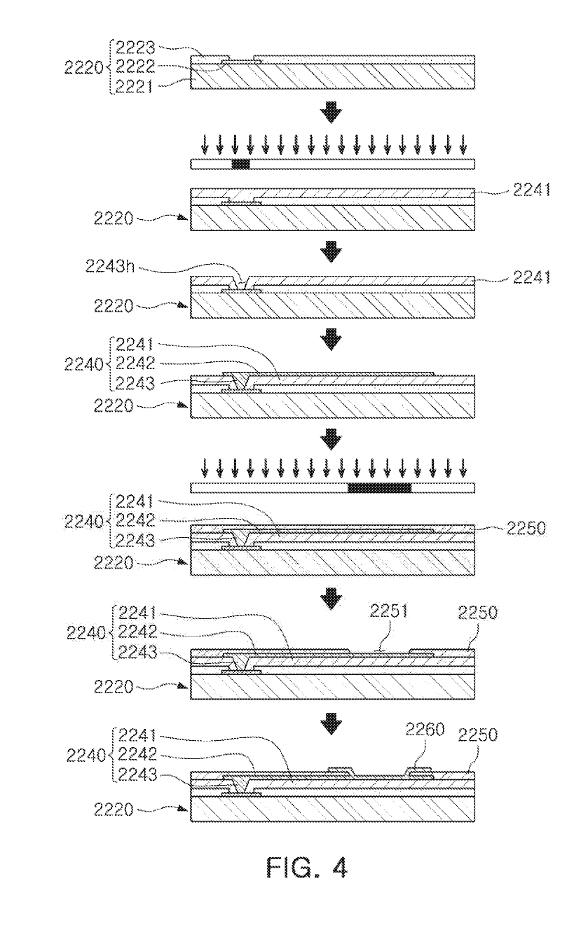

FIGS. 3A and 3B are schematic cross-sectional views illustrating states of a fan-in semiconductor package before and after being packaged, and FIG. 4 is schematic cross-sectional views illustrating a packaging process of a fan-in semiconductor package.

Referring to FIGS. 3A to 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide film, a nitride film, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as a photoimagable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a small size. In addition, due to the disadvantage described above, the fan-in semiconductor package may not be directly mounted and used on the mainboard of the electronic device. The reason is that even in the case in which a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in semiconductor package on the mainboard of the electronic device.

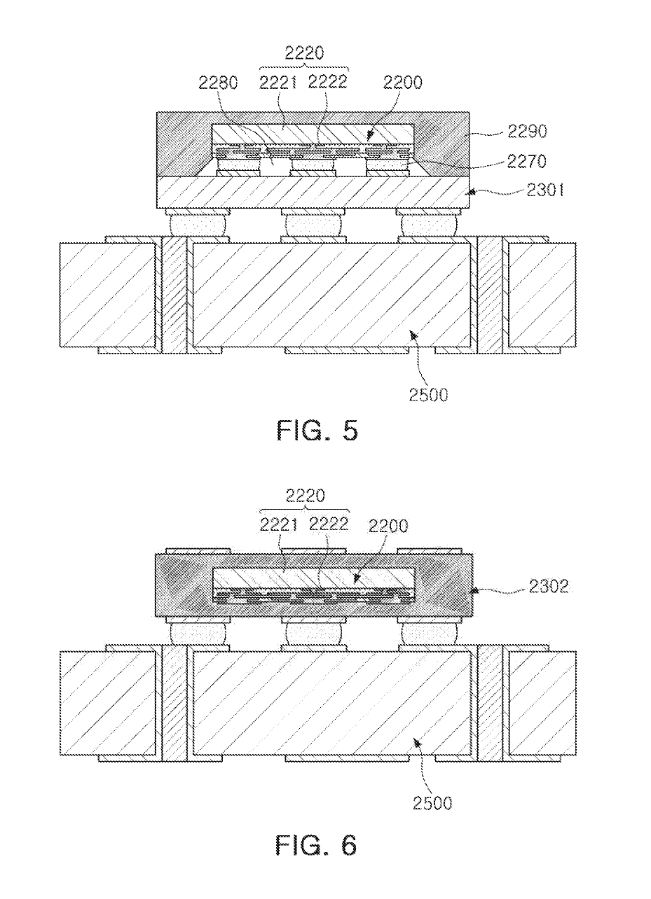

FIG. 5 is a schematic cross-sectional view illustrating a case in which a fan-in semiconductor package is mounted on an interposer substrate and is ultimately mounted on a mainboard of an electronic device, and FIG. 6 is a schematic cross-sectional view illustrating a case in which a fan-in semiconductor package is embedded in an interposer substrate and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed once more through an interposer substrate 2301, and the fan-in semiconductor package 2200 may be ultimately mounted on a mainboard 2500 of an electronic device in a state in which it is mounted on the interposer substrate 2301. In this case, solder balls 2270, and the like, may be fixed by an underfill resin 2280, or the like, and an outer side of the semiconductor chip 2220 may be covered with an encapsulant 2290, or the like. Alternatively, a fan-in semiconductor package 2200 may be embedded in a separate interposer substrate 2302, connection pads 2222, that is, I/O terminals, of a semiconductor chip 2220 may be redistributed once more by the interposer substrate 2302 in a state in which the fan-in semiconductor package 2200 is embedded in the interposer substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate interposer substrate and be then mounted on the mainboard of the electronic device through a packaging process or may be mounted and used on the mainboard of the electronic device in a state in which it is embedded in the interposer substrate.

Fan-Out Semiconductor Package

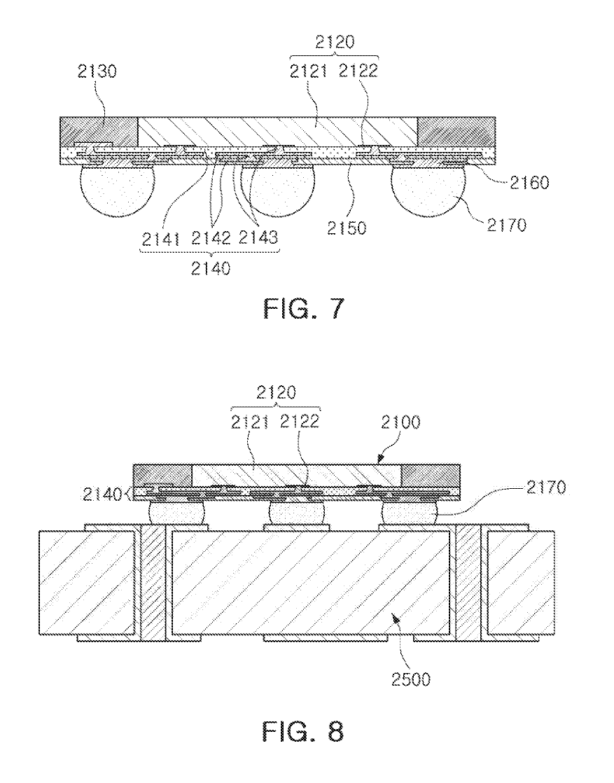

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2140, and an underbump metal layer 2160 may further be formed in openings of the passivation layer 2150. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

In the present manufacturing process, the connection member 2140 may be formed after the encapsulant 2130 is formed outside the semiconductor chip 2120. In this case, a process for the connection member 2140 is performed from the via connecting the redistribution layers and the connection pads 2122 of the semiconductor chip 2120 to each other and the redistribution layers, and the vias 2143 may thus have a width that becomes small as they become to the semiconductor chip (see an enlarged region).

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in the case in which a size of the semiconductor chip is decreased, a standardized ball layout may be used in the fan-out semiconductor package as it is, such that the fan-out semiconductor package may be mounted on the mainboard of the electronic device without using a separate interposer substrate, as described below.

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate interposer substrate, or the like.

As described above, since the fan-out semiconductor package may be mounted on the mainboard of the electronic device without using the separate interposer substrate, the fan-out semiconductor package may be implemented at a thickness lower than that of the fan-in semiconductor package using the interposer substrate. Therefore, the fan-out semiconductor package may be miniaturized and thinned. In addition, the fan-out semiconductor package has excellent thermal characteristics and electrical characteristics, such that it is particularly appropriate for a mobile product. Therefore, the fan-out semiconductor package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the mainboard of the electronic device, or the like, as described above, and protecting the semiconductor chip from external impacts, and is a concept different from that of a printed circuit board (PCB) such as an interposer substrate, or the like, having a scale, a purpose, and the like, different from those of the fan-out semiconductor package, and having the fan-in semiconductor package embedded therein.

A fan-out semiconductor package in which connection pads of a semiconductor chip and a redistribution layer are connected to each other using wire posts manufactured by a wire bonding process will hereinafter be described in detail with reference to the accompanying drawings.

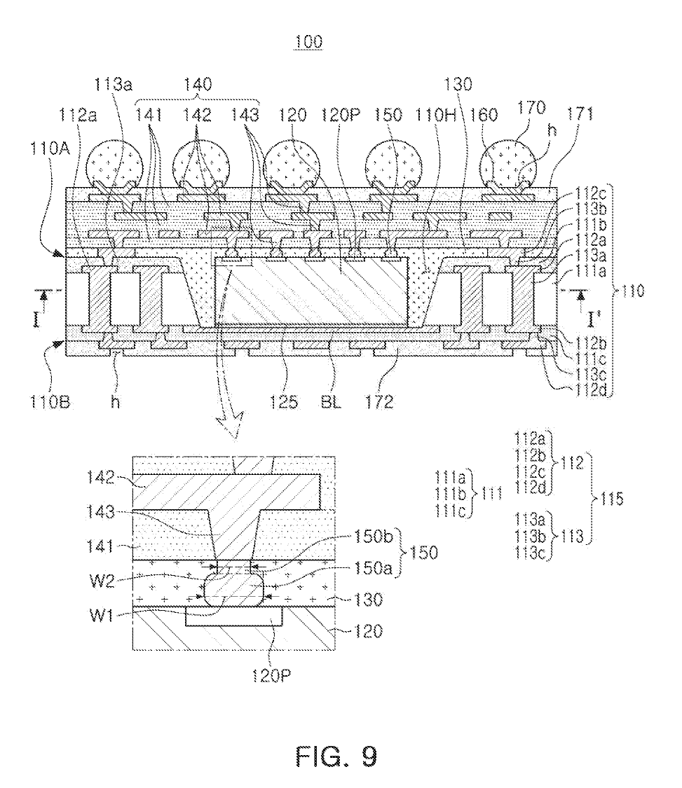

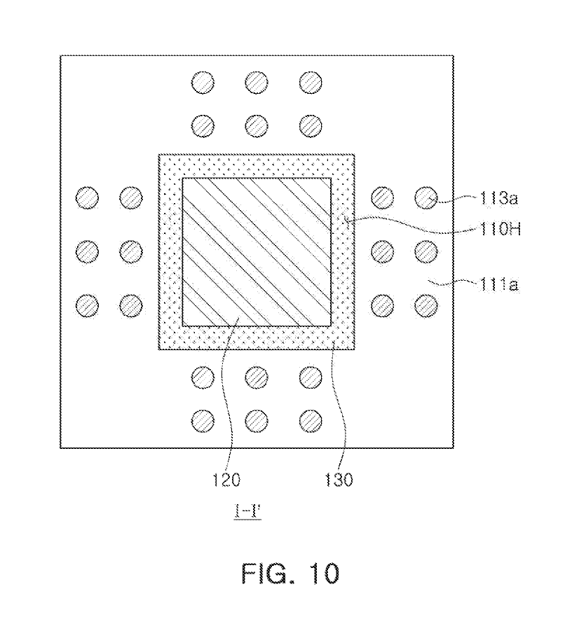

FIG. 9 is a side cross-sectional view illustrating a fan-out semiconductor package according to an exemplary embodiment in the present disclosure. FIG. 10 is a plan view taken along line I-I′ of the fan-out semiconductor package of FIG. 9.

Referring to FIGS. 9 and 10, a fan-out semiconductor package 100 according to the present exemplary embodiment may include a frame 110 having a first surface 110A in which a recess portion 110H is formed and a second surface 110B opposing the first surface 110A, a stopper layer BL disposed on a bottom surface of the recess portion 110H, a semiconductor chip 120 disposed on the stopper layer BL, and an encapsulant 130 filling at least portions of the recess portion 110H and covering the semiconductor chip 120. The stopper layer BL may have a planar area greater than that of the inactive surface of the semiconductor chip 120. The bottom surface of the recess portion 110H may have a planar area greater than that of the inactive surface of the semiconductor chip 120.

The semiconductor chip 120 may have an active surface having connection pads 120P disposed thereon and an inactive surface opposing the active surface, and the inactive surface of the semiconductor chip 120 may be attached to the stopper layer BL by an adhesive member 125. For example, the adhesive member 125 may be any known adhesive member, such as a die attach film (DAF).

The frame 110 according to the present exemplary embodiment may include a first insulating layer 111a corresponding to a core layer, second and third insulating layers 111b and 111c disposed on opposite surfaces of the first insulating layer 111a, respectively, and a wiring structure 115 connecting the first surface 110A and the second surface 110B to each other. The wiring structure 115 may include connection via layers 113 and wiring layers 112 electrically connected to each other through the connection via layers 113.

The fan-out semiconductor package 100 according to the present exemplary embodiment may further include a connection member 140 disposed on the first surface 110A of the frame 110. The connection member 140 may include redistribution layers 142 and 143 connected to the wiring structure 115 and the connection pads 120P. The redistribution layers may include connection vias 143 and wiring patterns 142 electrically connected to each other through the connection vias 143.

In the present exemplary embodiment, wire posts 150 may be disposed on the connection pads 120P of the semiconductor chip 120. The wire post 150 may penetrate through the encapsulant 130, and may have an upper surface substantially coplanar with a surface of the encapsulant 130. The connection via 143 of the redistribution layer may be connected to the upper surface of the wire post 150. As described above, the connection pads 120P and the redistribution layers 142 and 143 may be connected to each other by the wire posts 150. The connection pads 120P may be electrode pads of a bare chip on which a bonding metal (for example, Au, Cu, or an alloy thereof) is not formed. For example, the connection pads 120P may be formed of a metal such as Al.

The wire posts 150 according to the present exemplary embodiment may be formed of a bonding wire. Since the wire post is formed by a wire bonding process, the wire post 150 may have a unique structure including a body portion 150a and a lead portion 150b. In detail, the body portion 150a may be disposed on the connection pad 120P and may have a first width W1, and the lead portion 150b may be disposed on the body portion 150a and may have a second width W2 smaller than the first width W1. Since the body portion 150a, which is a lower structure, has a relatively large width, the body portion 150a may stably support the lead portion 150b providing a sufficient height.

A shape of the body portion 150a may be determined by an injection port (particularly, an internal structure) of a wire bonding device called a capillary, and a shape of the lead portion 150b may be defined by an angle and a speed at which the injection port of the wire bonding device is led. For example, the wire post 150 may be formed of a general wire bonding metal such as Au, Cu, or an alloy thereof.

The fan-out semiconductor package 100 according to the present exemplary embodiment may further include a first passivation layer 171 disposed on the connection member 140 and a second passivation layer 172 disposed on the second surface of the frame 110. The first passivation layer 171 may have openings h exposing partial regions of the wiring patterns 142. Underbump metal layers 160 may be disposed in the openings of the first passivation layer 171 to be connected to the partial regions of the wiring patterns 142. Electrical connection structures 170 may be disposed on the underbump metal layers 160 to be electrically connected to the wiring patterns 142 through the underbump metal layers 160.

The recess portion 110H according to the present exemplary embodiment may have a blind recess portion structure in which it is opened in the first surface 110A of the frame 110 and is closed in the second surface 110B of the frame 110.

The recess portion 110H may be formed by selectively applying an etching process such as a sandblast process to the first surface 110A of the frame 110. In this process, the stopper layer BL may be used in order to etch the frame 110 up to a determined position. The stopper layer BL may define the bottom surface of the recess portion 110H. The stopper layer BL may be formed of a material having an etching rate lower than that of the insulating layers of the frame 110. For example, the stopper layer BL may include a metal such as copper (Cu). In the present exemplary embodiment, the stopper layer BL may be a metal pattern formed together with a wiring pattern (that is, a second wiring layer 112b) of the wiring structure 115 disposed on the same level. A region of the stopper layer BL exposed by the recess portion 110H may have a thickness less than a thickness of an edge region of the stopper layer BL covered by the first insulating layer 111a.

In another example, the stopper layer BL is not limited to including the metal, but may include an insulating material. For example, the stopper layer BL may be a photosensitive polymer such as a dry film photoresist (DFR).

The respective components included in the fan-out semiconductor package 100 according to the present exemplary embodiment will hereinafter be described in more detail.

The frame 110 may reinforce rigidity of the fan-out semiconductor package 100 depending on certain materials, and serve to assist in uniformity of a thickness of the encapsulant 130. The frame 110 may have the wiring structure 115 including first to fourth wiring layers 112a, 112b, 112c, and 112d and first to third connection via layers 113a, 113b, and 113c. The frame 110 may include the third wiring layer 112c disposed on the inactive surface of the semiconductor chip 120, and may have a blind type recess portion 110H. The fourth wiring layer 112d may be thus provided as a backside redistribution layer for the semiconductor chip 120 without performing a process of forming a separate backside redistribution layer.

The frame 110 may include the first insulating layer 111a, the first and second wiring layers 112a and 112b disposed on the opposite surfaces of the first insulating layer 111a, respectively, the first connection via layers 113a penetrating through the first insulating layer 111a and connecting the first and second wiring layers 112a and 112b to each other. In addition, the frame 110 may include the second insulating layer 111b disposed on one surface of the first insulating layer 111a and covering the first wiring layer 112a, the third insulating layer 111c disposed on the other surface of the first insulating layer 111a and covering the second wiring layer 112b, the third wiring layer 112c disposed on the second insulating layer 111b, the fourth wiring layer 112d disposed on the third insulating layer 111c, the second connection via layers 113b penetrating through the second insulating layer 111b and electrically connecting the first and third wiring layers 112a and 112c to each other, and the third connection via layers 113c penetrating through the third insulating layer 111c and electrically connecting the second and fourth wiring layers 112b and 112d to each other.

In the present exemplary embodiment, the recess portion 110H may penetrate through the first and second insulating layers 111a and 111b, but may not penetrate through the third insulating layer 111c due to the stopper layer BL. The first and second insulating layers 111a and 111b may provide sidewalls of the recess portion 110H, and the stopper layer BL may be disposed on the same level on the third insulating layer 111c together with a barrier pattern for a guide and the second wiring layer 112b. The stopper layer BL according to the present exemplary embodiment may be used as a heat dissipation member dissipating heat generated by the semiconductor chip 120. If necessary, the stopper layer BL may be connected to a ground and be used as an electromagnetic interference (EMI) blocking member.

The first to third insulating layers 111a, 111b, and 111c may include a thermosetting resin such as an epoxy resin or a thermoplastic resin such as a polyimide resin. In a specific example, each of the first to third insulating layers 111a, 111b, and 111c may include a resin mixed with an inorganic filler or impregnated together with an inorganic filler in a glass fiber, or the like, for example, prepreg, Ajinomoto Build up Film (ABF), FR-4, Bismaleimide Triazine (BT), or the like. When a material having high rigidity, such as prepreg including a glass fiber, or the like, is used as a material of each of the first to third insulating layers 111a, 111b, and 111c, the frame 110 may be utilized as a support member for controlling warpage of the fan-out semiconductor package 100.

The first insulating layer 111a may have a thickness greater than those of the second and third insulating layers 111b and 111c. The first insulating layer 111a may be basically relatively thick in order to maintain rigidity, and the second insulating layer 111b and the third insulating layer 111c may be introduced to form a larger number of wiring layers 112c and 112d. The second and third insulating layers 111b and 111c may include a material different from that of the first insulating layer 111a. For example, the first insulating layer 111a may be, for example, prepreg in which an insulating resin is impregnated together with an inorganic filler in a glass fiber, and the second and third insulating layers 111b and 111c may be an ABF or a PID film including an inorganic filler and an insulating resin. However, the materials of the first insulating layer 111a and the second and third insulating layers 111b and 111c are not limited thereto. The first connection via layer 113a penetrating through the first insulating layer 111a may have a diameter greater than those of the second and third connection via layers 113b and 113c.

The first to fourth wiring layers 112a, 112b, 112c, and 112d may redistribute the connection pads 120P of the semiconductor chip 120 together with the redistribution layers 142 and 143 of the connection member 140. For example, the first to fourth wiring layers 112a, 112b, 112c, and 112d may include a conductive material such as copper (Cu), aluminum (Al), silver (Ag), tin (Sn), gold (Au), nickel (Ni), lead (Pb), titanium (Ti), or alloys thereof.

The first to fourth wiring layers 112a, 112b, 112c, and 112d may perform various functions depending on designs of corresponding layers. For example, the first to fourth wiring layers 112a, 112b, 112c, and 112d may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. The stopper layer BL may be electrically connected to the ground.

Thicknesses of the first to fourth wiring layers 112a, 112b, 112c, and 112d may be greater than those of the wiring patterns 142 of the connection member 140. Since the wiring structure 115 of the frame 110 is formed by a substrate process, the wiring structure 115 may be formed to have a relatively large size, and since the redistribution layers 142 and 143 of the connection member 140 are formed by a semiconductor process, the redistribution layers 142 and 143 may also be formed to have relatively small sizes.

The first to third connection via layers 113a, 113b, and 113c may electrically connect the first to fourth wiring layers 112a, 112b, 112c, and 112d formed on different layers to each other, resulting in an electrical path in the frame 110. The first to third connection via layers 113a, 113b, and 113c may be formed of a conductive material. The first connection via layer 113a may have a cylindrical shape or a hourglass shape, and the second and third connection via layers 113b and 113c may have tapered shapes of which directions are opposite to each other in relation to the first insulating layer 111a.

The semiconductor chip 120 may be an integrated circuit (IC) provided in an amount of several hundred to several million or more elements integrated in a single chip. The semiconductor chip 120 may be, for example, a processor chip (more specifically, an application processor (AP)) such as a central processor (for example, a CPU), a graphic processor (for example, a GPU), a field programmable gate array (FPGA), a digital signal processor, a cryptographic processor, a micro processor, a micro controller, or the like, but is not limited thereto. In addition, the semiconductor chip 120 may be a memory chip such as a volatile memory (such as a DRAM), a non-volatile memory (such as a ROM), a flash memory, or the like, but is not limited thereto.

The semiconductor chip 120 may be formed on the basis of an active wafer, and a base material of a body of the semiconductor chip 120 may be silicon (Si), germanium (Ge), gallium arsenide (GaAs), or the like. Various circuits may be formed on the body. The connection pads 120P may electrically connect the semiconductor chip 120 to other components. A material of each of the connection pads 120P may be a conductive material such as aluminum (Al), or the like. A passivation layer exposing the connection pads 120P may be formed on the body, and may be an oxide film, a nitride film, or the like, or a double layer of an oxide layer and a nitride layer. An insulating layer, and the like, may also be further disposed in required positions. The semiconductor chip 120 may be a bare die, but may further include a redistribution layer formed on the active surface thereof, if necessary.

The encapsulant 130 may protect the frame 110, the semiconductor chip 120, and the like. An encapsulation form of the encapsulant 130 is not particularly limited, but may be a form in which the encapsulant 130 packs the frame 110 and the semiconductor chip 120. For example, the encapsulant 130 may cover the first surface 110A of the frame 110 and the active surface of the semiconductor chip 120, and fill spaces between the sidewalls of the recess portion 110H and side surfaces of the semiconductor chip 120. The encapsulant 130 may fill the recess portion 110H to thus serve as an adhesive and reduce buckling of the semiconductor chip 120 depending on certain materials.

The encapsulant 130 may include an insulating material, for example, a thermosetting resin such as an epoxy resin or a thermoplastic resin such as a polyimide resin. In a specific example, the encapsulant 130 may include a resin mixed with an inorganic filler or impregnated together with an inorganic filler in a glass fiber. For example, prepreg, ABF, FR-4, BT, or the like, may be used as a material of the encapsulant 130. Alternatively, the encapsulant 130 may include a photoimagable encapsulant (PIE) resin.

The connection member 140 may redistribute the connection pads 120P of the semiconductor chip 120, and may electrically connect the first to fourth wiring layers 112a, 112b, 112c, and 112d of the frame 110 to the connection pads 120P of the semiconductor chip 120. Several tens to several millions of connection pads 120P of the semiconductor chip 120 having various functions may be redistributed by the connection member 140, and may be physically or electrically externally connected through the electrical connection structures 170 depending on the functions. The connection member 140 may include the insulating layers 141 disposed on the frame 110 and the active surface of the semiconductor chip 120, the wiring patterns 142 disposed on the insulating layers 141, and the connection vias 143 penetrating through the insulating layers 141 and connecting the connection pads 120P and the third wiring layer 112c to the wiring patterns 142 adjacent to the connection pads 120P and the third wiring layer 112c or connecting the wiring patterns 142 disposed on different layers to each other.

A material of each of the insulating layers 141 may be a photosensitive insulating material such as a PID resin, in addition to the insulating material as described above. When the insulating layers 141 have photosensitive properties, the insulating layers 141 may be formed to have a smaller thickness, and a fine pitch of the connection vias 143 may be achieved more easily. The insulating layers 141 may be photosensitive insulating layers including an insulating resin and an inorganic filler. When the insulating layers 141 are multiple layers, materials of the insulating layers 141 may be the same as each other, and may also be different from each other, if necessary. When the insulating layers 141 are the multiple layers, the insulating layers 141 may be integrated with each other depending on a process, such that a boundary therebetween may also not be apparent.

The wiring patterns 142 of the connection member 140 may serve to substantially redistribute the connection pads 120P. Each of the wiring patterns 142 may include, for example, a conductive material such as copper (Cu), aluminum (Al), silver (Ag), tin (Sn), gold (Au), nickel (Ni), lead (Pb), titanium (Ti), or alloys thereof. The redistribution layers 142 and 143 may perform various functions depending on designs of corresponding layers, and may include, for example, ground patterns, power patterns, and signal patterns, and the like.

The connection vias 143 may electrically connect the wiring patterns 142, the connection pads 120P, and the third wiring layer 112c, and the like, formed on different layers to each other, resulting in an electrical path in the fan-out semiconductor package 100.

The first and second passivation layers 171 and 172 may protect the connection member 140 and the frame 110 from external physical or chemical damage. The first passivation layer 171 may have the openings h exposing at least portions of the wiring pattern 142 of the connection member 140. The second passivation layer 172 may have openings h exposing at least portions of the fourth wiring layer 112d of the frame 110. The numbers of openings h formed in the first and second passivation layers 171 and 172 may be several tens to several millions. A material of each of the first and second passivation layers 171 and 172 may be a solder resist, in addition to the insulating material as described above.

The underbump metal layers 160 may improve connection reliability of the electronic connection structures 170, resulting in improvement of board level reliability of the fan-out semiconductor package 100. The underbump metal layers 160 may be connected to the wiring patterns 142 of the connection member 140 exposed through the openings of the first passivation layer 171. The underbump metal layers 160 may be formed in the openings of the first passivation layer 171 by any known metallization method using any known conductive material such as a metal, but are not limited thereto.

The electrical connection structures 170 may physically or electrically externally connect the fan-out semiconductor package 100. For example, the fan-out semiconductor package 100 may be mounted on the mainboard of the electronic device through the electrical connection structures 170. Each of the electrical connection structures 170 may be formed of a conductive material, for example, a low melting point metal such as an Sn—Al—Cu alloy. However, this is only an example, and a material of each of the electrical connection structures 170 is not particularly limited thereto. Each of the electrical connection structures 170 may be a land, a ball, a pin, or the like. The electrical connection structures 170 may be formed as a multilayer or single layer structure.

The number, an interval, a disposition form, and the like, of electrical connection structures 170 are not particularly limited, but may be sufficiently modified depending on design particulars by those skilled in the art. For example, the electrical connection structures 170 may be provided in an amount of several tens to several thousands according to the number of connection pads 120P, or may be provided in an amount of several tens to several thousands or more or several tens to several thousands or less. When the electrical connection structures 170 are formed of the low melting point metal, the electrical connection structures 170 may cover side surfaces of the underbump metal layers 160 extending onto one surface of the first passivation layer 171, and connection reliability may be more excellent.

At least one of the electrical connection structures 170 may be disposed in a fan-out region. The fan-out region refers to a region except for a region in which the semiconductor chip 120 is disposed. A fan-out semiconductor package may have excellent reliability as compared to a fan-in semiconductor package, may implement a plurality of input/output (I/O) terminals, and may facilitate a 3D interconnection. In addition, as compared to a ball grid array (BGA) package, a land grid array (LGA) package, or the like, the fan-out package may be manufactured to have a small thickness, and may have price competitiveness.

Meanwhile, although not illustrated, a metal film may be formed on the sidewalls of the recess portion 110H, if necessary, in order to dissipate heat or block electromagnetic waves. In addition, a plurality of semiconductor chips 120 performing functions that are the same as or different from each other may be disposed in the recess portion 110H, if necessary. In addition, a separate passive component such as an inductor, a capacitor, or the like, may be disposed in the recess portion 110H. For example, surface mounting technology (SMT) components such as an inductor or a capacitor may be disposed on surfaces of the first and second passivation layers 171 and 172.

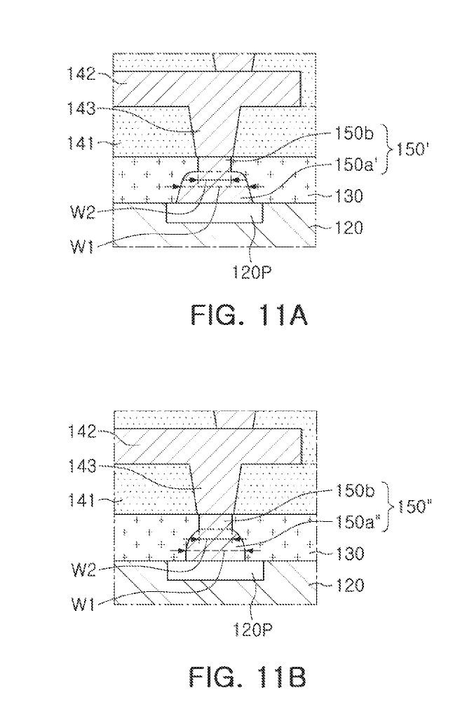

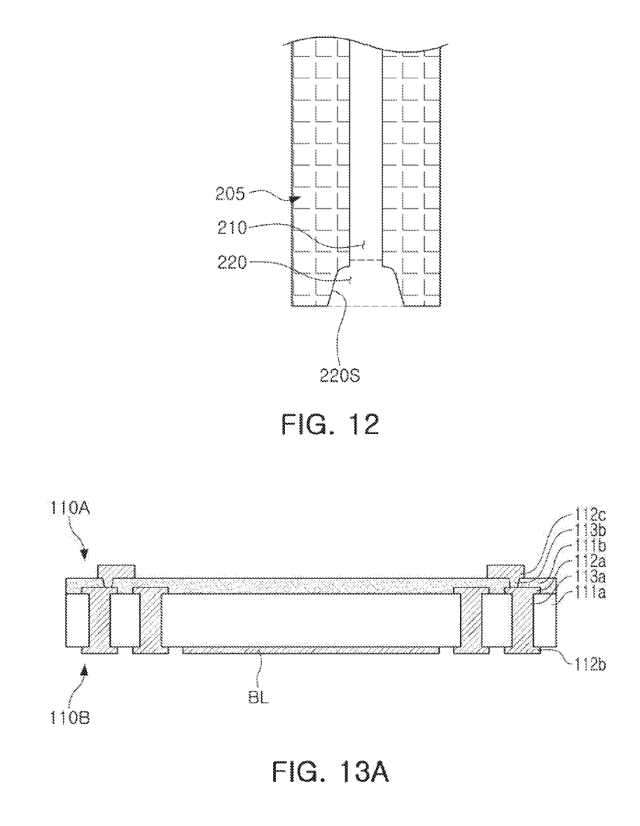

FIGS. 11A and 11B are cross-sectional views illustrating various types of wire posts that may be used in an exemplary embodiment in the present disclosure, and FIG. 12 is a cross-sectional view illustrating an example of an injection port of a wire bonding device.

Referring to FIG. 11A, a wire post 150′ according to the present exemplary embodiment may include a body portion 150a′ disposed on the connection pad 120P and having a trapezoidal cross section and a lead portion 150b disposed on the body portion 150a′. The body portion 150a′ of the wire post 150′ may have a first width W1 that is gradually decreased toward the top, and the lead portion 150b of the wire post 150′ may have a width W2 smaller than that of an upper end of the body portion.

The injection port 205 of the wire bonding device illustrated in FIG. 12 may be used to manufacture the wire post 150′ illustrated in FIG. 11A. Referring to FIG. 12, when a bonding metal is injected through an injection hole 210 to fill an internal structure 220 connected to a bonding forming surface (the connection pad), the body portion 150a′ may be formed. That is, the body portion 150a′ of the wire post 150′ corresponding to the internal structure 220 of the injection port 205 may be formed. Meanwhile, after the body portion 150a′ is formed, the lead portion 150b may be determined by pulling the injection port 205 of the wire bonding device to be separated from the body portion 150a′. The lead portion 150b may be formed to have a diameter that is the same as or smaller than that of the injection hole 220 depending on a direction in which the injection port is led and a speed at which the injection port is led.

Referring to FIG. 11B, a wire post 150″ according to the present exemplary embodiment may include a body portion 150a″ disposed on the connection pad 120P and having a dome structure and a lead portion 150b disposed on the body portion 150a″. The body portion 150a″ of the wire post 150″ may be formed in the dome structure to have a first width W1. Such a shape of the body portion 150a″ may be appropriately changed by designing the internal structure of the injection port 205 of the wire bonding device as described above. The lead portion 150b of the wire post 150″ may have a width W2 smaller than the first width W1 of the body portion 150a″.

Since the body portion 150a′ or 150a″ of the wire post, which is a lower structure, has a relatively large width, the body portion 150a′ or 150a″ may stably support the lead portion 150b providing a sufficient height. The body portion 150a′ or 150a″ may be appropriately designed using the injection port of the wire bonding device, and a wire height of the entire wire post may be appropriately selected using the lead portion 150b.

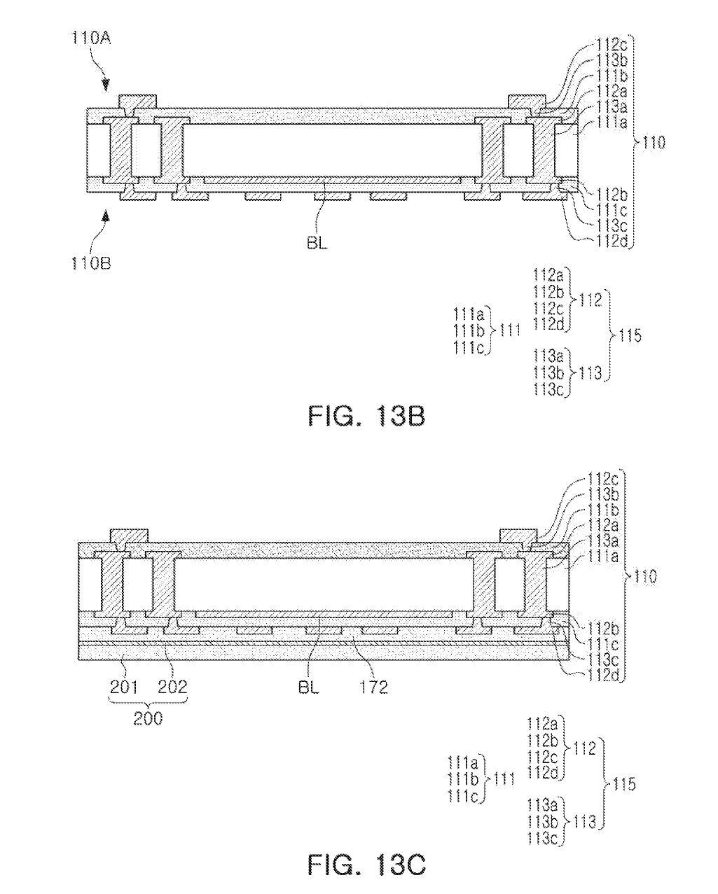

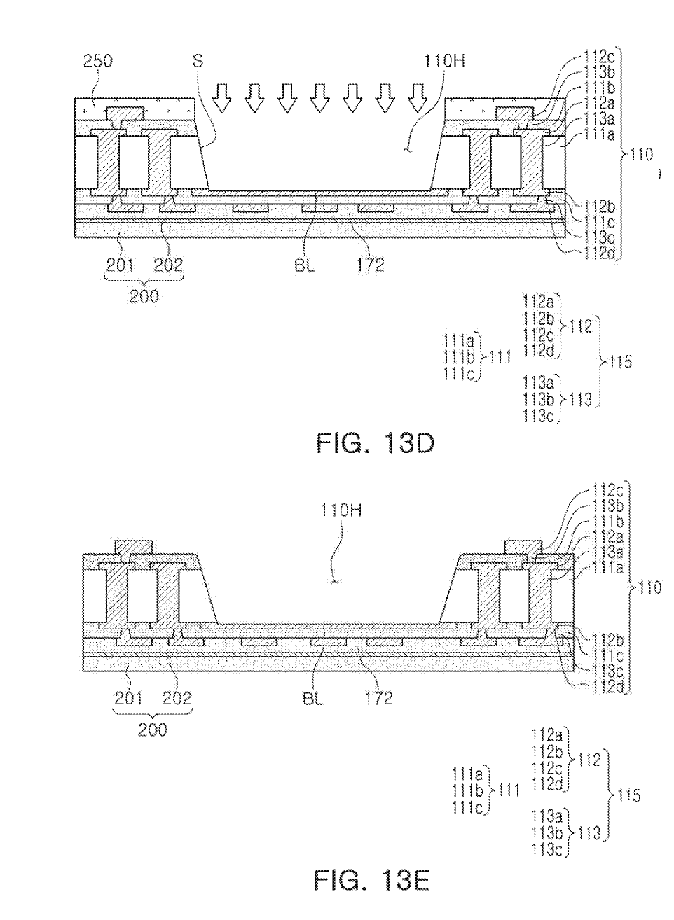

FIGS. 13A through 13E are cross-sectional views illustrating main processes of forming a frame.

First, referring to FIG. 13A, the first insulating layer 111a may be prepared, the first and second wiring layers 112a and 112b and the first connection via layers 113a may be formed on and in the first insulating layer 111a, respectively, and the stopper layer BL may be formed on a surface of the first insulating layer 111a on which the second wiring layer 112b is disposed.

The first insulating layer 111a may be, for example, a copper clad laminate (CCL). Holes for the first connection via layers 113a may be formed using a mechanical drill and/or a laser drill. The first and second wiring layers 112a and 112b and the first connection via layers 113a may be formed by any known plating process.

The stopper layer BL may be formed on the surface of the first insulating layer 111a on which the second wiring layer 112b is disposed. In a process of forming a recess portion to be described below, the stopper layer BL may serve as an etching barrier determining a depth of the recess portion. In the present exemplary embodiment, the stopper layer BL may be a metal pattern formed together with the second wiring layer 112b by the same process. For example, the stopper layer BL may include a metal such as copper (Cu).

Then, referring to FIG. 13B, the second and third insulating layers 111b and 111c and a desired wiring structure 115 may be formed on the opposite surfaces of the first insulating layer 111a.

In the present process, the second and third insulating layers 111b and 111c may be formed by laminating and hardening insulating films such as ABFs. The third and fourth wiring layers 112c and 112d and the second and third connection via layers 113b and 113c may be formed on and in the second and third insulating layers 111b and 111c, respectively, by a plating process. Holes for the second and third connection via layers 113b and 113c may be formed using a mechanical drill and/or a laser drill, similar to the holes for the first connection via layers 113a.

Then, referring to FIG. 13C, the second passivation layer 172 may be formed on the second surface 110B of the frame 110 prepared in the process described above, and a carrier film 200 may be attached to the second passivation layer 172.

A material of the second passivation layer 172 may be a solder resist, in addition to the various insulating materials described above. The carrier film 200 may be disposed on the second surface 110B on which the second passivation layer 172 is formed, and may be used as a support for treating the frame 110 in a subsequent process such as a process of forming a recess portion, or the like. The carrier film 200 used in the present exemplary embodiment may be a copper clad laminate such as a DCF including an insulating layer 201 and a metal layer 202.

Then, referring to FIG. 13D, a mask layer 250 having an open region may be formed on the first surface 110A of the frame 110, and an etching process for forming the recess portion may be performed.

A DFR may be formed on the first surface 110A of the frame 110 and be then patterned to form the mask layer 250 having the open region defining the recess portion. The recess portion 110H penetrating through the first and second insulating layers 111a and 111b may be formed by an etching process such as a sandblast process. In this case, the stopper layer BL may act as the etch stop layer as described above to define a depth of the recess portion 110H. A region of the stopper layer BL exposed by the recess portion 110H may have a thickness less than a thickness of an edge region of the stopper layer BL covered by the first insulating layer 111a, in a case in which an over etching effect of the etching process occurs.

When a process of forming the recess portion 110H ends, as illustrated in FIG. 13E, the mask layer 250 may be removed, and the frame 110 including the recess portion 110H and the wiring structure 115 may be provided.

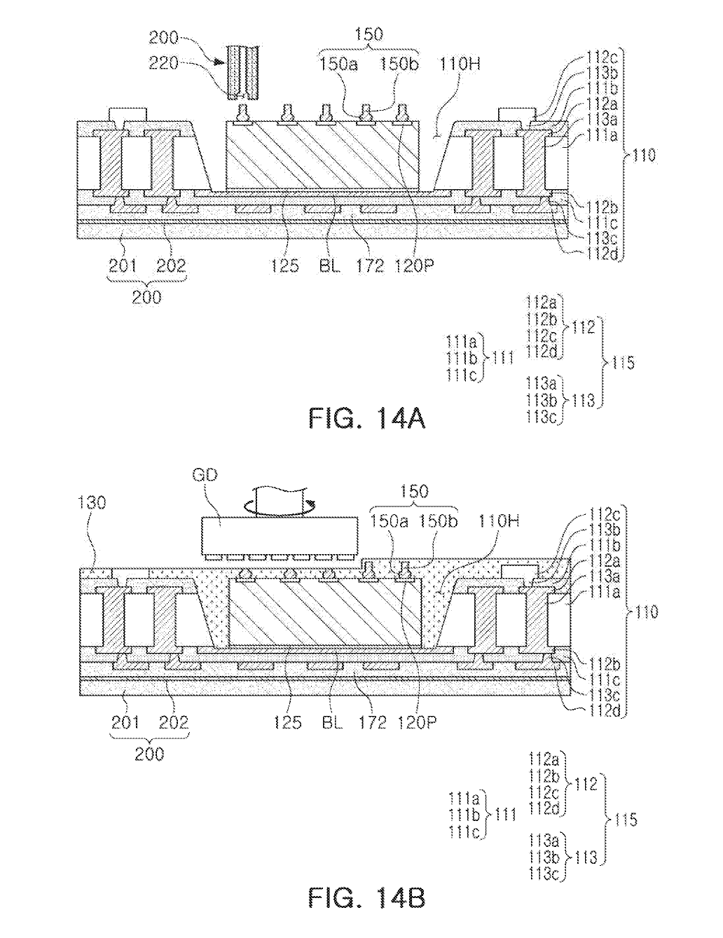

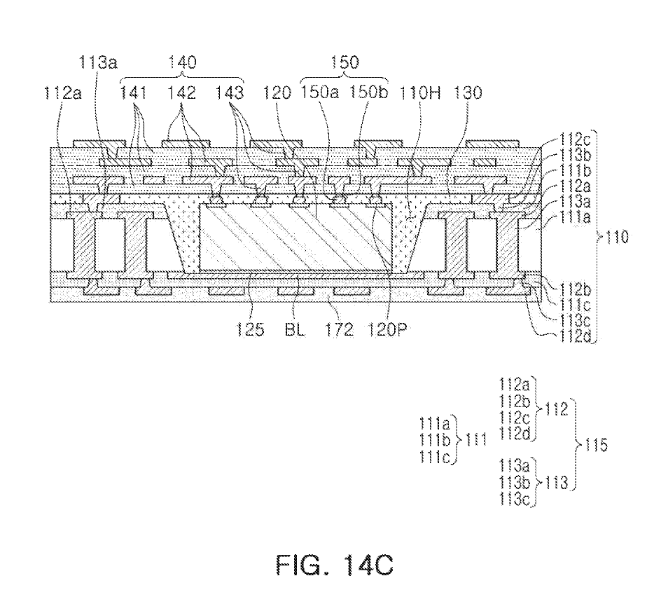

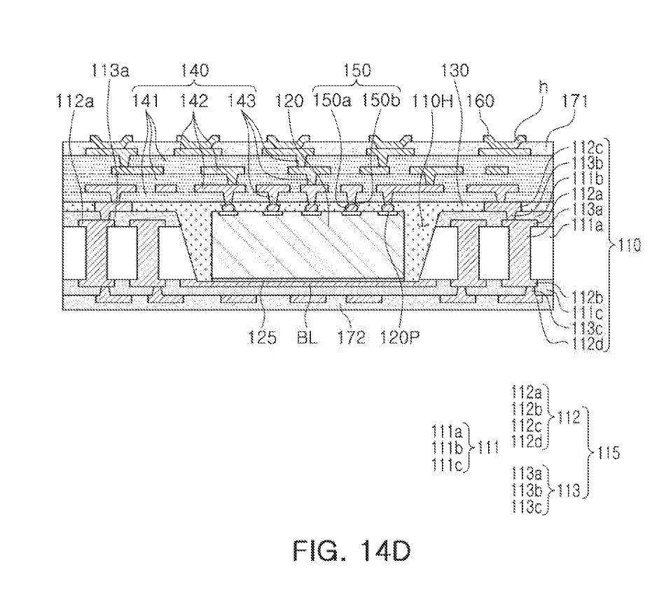

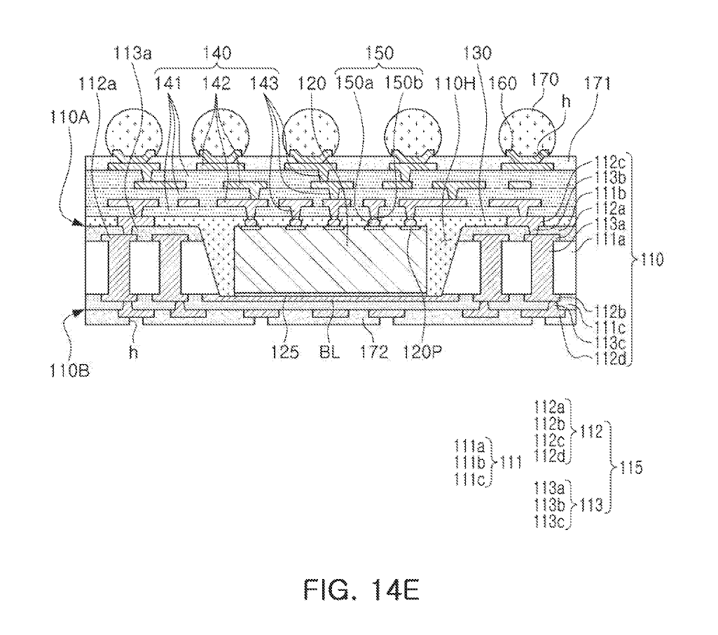

FIGS. 14A through 14E are cross-sectional views illustrating main processes of manufacturing a fan-out semiconductor package. The present manufacturing process may be understood as a process of manufacturing the fan-out semiconductor package using the frame 110 manufactured in the previous process.

Referring to FIG. 14A, the semiconductor chip 120 may be disposed in the recess portion 110H and be attached to the stopper layer BL.

The semiconductor chip 120 may be attached to the stopper layer BL using the adhesive member 125 such as the DAF. Meanwhile, the wire posts 150 may be formed on the connection pads 120P of the semiconductor chip 120 using the wire bonding device. Conductive posts may be formed on the connection pads 120P on which separate conductive bumps are not formed, using the general wire bonding device. As described above, the wire post 150 may include the body portion 150a disposed on the connection pad 120P and having the first width and the lead portion 150b disposed on the body portion 150a and having the second width smaller than the first width. A height of the wire post 150 may be the same as or higher than that of the third wiring layer 112c.

Then, referring to FIG. 14B, the first surface 110A of the frame 110 and the semiconductor chip 120 may be encapsulated using the encapsulant 130, and a grinding process may be performed so that the wire posts 150 and the third wiring layer 112c are exposed, using a grinding device (GD).

The encapsulants 130 may be formed by laminating and then hardening a film such as an ABF. The encapsulant 130 may be formed to cover the wire posts 150 together with at least the first surface 110A of the frame. The wire posts 150 and the third wiring layer 112c may be exposed on a surface of the encapsulant 130 by the present grinding process, and the surface of the encapsulant 130 and upper surfaces of the wire posts 150 and the third wiring layer 112c may be substantially coplanar with each other. Since only a portion of the lead portion 150b relatively high in the wire post 150 is removed by such a grinding process, the final wire post 150 may include the body portion 150a and the remaining lead portion 150b. However, according to other some exemplary embodiments, in the final wire post, the lead portion may be completely removed and only the body portion may remain, depending on a grinding thickness.

Then, referring to FIG. 14C, the connection member 140 including the redistribution layers 142 and 143 may be formed on the encapsulant 130.

The insulating layers 141 may be formed by applying and hardening insulating materials such as PIDs, and the redistribution layers 142 and 143 may be formed by a plating process. The redistribution layers 142 and 143 may include the wiring patterns 142 and the connection vias 143, and may be connected to the wire posts 150 and the third wiring layer 112c through the connection vias 143 formed in insulating layers 141 adjacent thereto. The numbers of layers of the insulating layers 141, the wiring patterns 142, and the connection vias 143 may be different from one another depending on a design.

Then, referring to FIG. 14D, the first passivation layer 171 may be formed on the connection member 140, and the underbump metal layers 160 may be formed by any known metallization method.

The openings exposing partial regions of the wiring patterns 142 may be formed in the first passivation layer 171, and the underbump metal layers 160 may be formed in the openings of the first passivation layer 171 to be connected to the partial regions of the wiring patterns 142. The underbump metal layers 160 may be formed in the openings of the first passivation layer 171 by any known metallization method using any known conductive material such as a metal, but are not limited thereto.

Then, referring to FIG. 14E, the carrier film 200 may be removed, and the electrical connection structures 170 may be formed on the underbump metal layers 160.

Each of the electrical connection structures 170 may be formed of a conductive material, for example, a low melting point metal such as an Sn—Al—Cu alloy. Each of the electrical connection structures 170 may be a land, a ball, a pin, or the like. The electrical connection structures 170 may be formed as a multilayer or single layer structure. The number, an interval, a disposition form, and the like, of electrical connection structures 170 are not particularly limited, but may be sufficiently modified depending on design particulars by those skilled in the art. For example, the electrical connection structures 170 may be provided in an amount of several tens to several thousands according to the number of connection pads 120P, or may be provided in an amount of several tens to several thousands or more or several tens to several thousands or less. The electric connection structures 170 may be disposed on the mainboard of the electronic device or on another package and be fixed to the mainboard or another package while being electrically connected to the mainboard or another package by a reflow process.

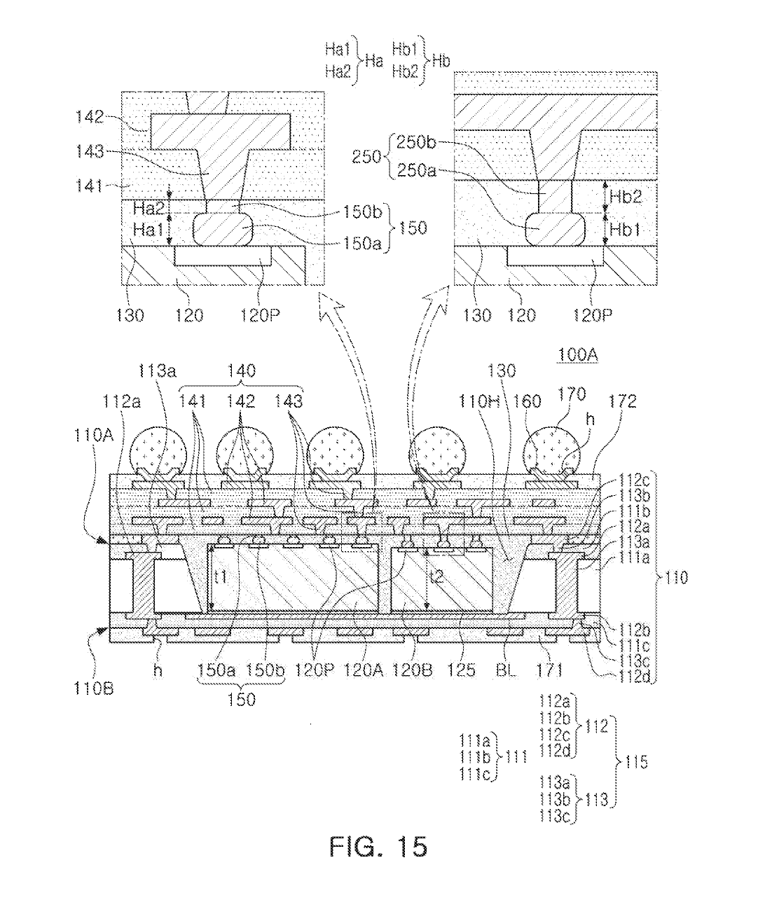

FIG. 15 is a side cross-sectional view illustrating a fan-out semiconductor package according to an exemplary embodiment in the present disclosure.

Referring to FIG. 15, it may be understood that a fan-out semiconductor package 100A according to the present exemplary embodiment is similar to the fan-out semiconductor package 100 illustrated in FIGS. 9 and 10 except that it includes first and second semiconductor chips 120A and 120B disposed in a recess portion 110H and first and second wire posts 150 and 250 are thus used. Components according to the present exemplary embodiments may be understood with reference to the description for the same or similar components of the fan-out semiconductor package 100 illustrated in FIGS. 9 and 10 unless explicitly described to the contrary.

The fan-out semiconductor package 100A according to the present exemplary embodiment may include the first and second semiconductor chips 120A and 120B disposed in the recess portion 110H and having different thicknesses. An encapsulant 130 may encapsulate the first and second semiconductor chips 120A and 120B to cover the first surface 110A of the frame 110.

The first wire posts 150 may be connected to connection pads 120P of the first semiconductor chip 120A, and the second wire posts 250 may be connected to connection pads 120P of the second semiconductor chip 120B. The first and second wire posts 150 and 250 may penetrate through the encapsulant 130 and be formed at different heights Ha and Hb to have upper surfaces substantially coplanar with an upper surface of the encapsulant 130.

As illustrated in FIG. 15, the second wire posts 250 may have the height Hb higher than the height Ha of the first wire posts 150 in order to compensate for a thickness difference between the first and second semiconductor chips 120A and 120B.

In the present exemplary embodiment, the first and second wire posts 150 and 250 may include body portions 150a and 250a disposed on the connection pads 120P and having a first width and lead portions 150b and 250b disposed on the body portions 150a and 250a and having a second width smaller than the first width, respectively. The body portions 150a and 250a of the first and second wire posts 150 and 250 may have substantially the same shape. The same shape may be obtained by using the same wire bonding device.

The body portions 150a and 250a of the first and second wire posts 150 and 250 may have substantially the same height Ha1=Hb1, but the lead portions 150b and 250b of the first and second wire posts 150 and 250 may have different heights Ha1 and Hb2 (Ha2<Hb2). For example, when the same wire bonding device is used, the body portions 150a and 250a of the first and second wire posts 150 and 250 are formed depending on a shape of an internal structure of an injection port of the wire bonding device, and may thus be formed to have the same shape and height. In addition, the lead portions 150b and 250b remaining after a grinding process are exposed on a surface of the encapsulant 130, and the lead portion 250b of the second wire post 250 may thus have the height Hb2 higher than the height Hb1 of the lead portion 150b of the first wire post 150.

A redistribution layers 142 of a connection member 140 disposed on the first surface 110A of the frame 110 may be connected to the first and second wire posts 150 and 250 together with a wiring structure 115 through connection vias 143.

Unlike the present exemplary embodiment, the first and second wire posts 150 and 250 may have different shapes. For example, even though the first and second wire posts 150 and 250 are formed by the same wire bonding device, in the first wire post 150 related to the first semiconductor chip 120A having a relatively great thickness, the lead portion 150b may be almost removed, and only the body portion 150a that is partially removed may remain, depending on a grinding thickness. Resultantly, the first wire post 150 may have a structure different from that of the second wire post 250 including both of the body portion 250a and the lead portion 250b. The first and second wire posts 150 and 250 may penetrate through the encapsulant 130, and may have upper surfaces substantially coplanar with a surface of the encapsulant 130.

As set forth above, according to the exemplary embodiments in the present disclosure, the wire posts formed by wire bonding may be formed on the connection pads (for example, Al pads) of the semiconductor chip to easily provide a connection structure between the semiconductor chip and the redistribution layer. Particularly, when a plurality of semiconductor chip mounted in one package have different thicknesses, wire posts having different heights for compensating for a thickness deviation may be provided to simplify a package process.

While exemplary embodiments have been shown and described above, it will be apparent to those skilled in the art that modifications and variations could be made without departing from the scope of the present invention as defined by the appended claims.

1. A fan-out semiconductor package comprising:
a frame including a plurality of insulating layers, a plurality of wiring layers disposed on the plurality of insulating layers, and a plurality of connection via layers penetrating through the plurality of insulating layers and electrically connecting the plurality of wiring layers to each other, and having a recess portion and a stopper layer disposed on a bottom surface of the recess portion;
a semiconductor chip disposed in the recess portion and having connection pads, an active surface on which the connection pads are disposed, and an inactive surface opposing the active surface and disposed on the stopper layer;
an encapsulant covering at least portions of the semiconductor chip and filling at least portions of the recess portion; and
a connection member disposed on the frame and the active surface of the semiconductor chip and including a redistribution layer electrically connecting the plurality of wiring layers of the frame and the connection pads of the semiconductor chip to each other,
wherein the connection pads of the semiconductor chip are electrically connected to the redistribution layer of the connection member through wire posts disposed on the connection pads of the semiconductor chip.

2. The fan-out semiconductor package of claim 1, wherein upper surfaces of the wire posts are coplanar with an upper surface of the encapsulant.

3. The fan-out semiconductor package of claim 2, wherein an upper surface of an uppermost wiring layer of the plurality of wiring layers of the frame or an upper surface of an uppermost connection via layer of the plurality of connection via layers is coplanar with the upper surfaces of the wire posts and the upper surface of the encapsulant.

4. The fan-out semiconductor package of claim 1, wherein the wire post includes a body portion disposed on the connection pad and having a first width and a lead portion disposed on the body portion and having a second width smaller than the first width.

5. The fan-out semiconductor package of claim 1, wherein the semiconductor chip includes a plurality of semiconductor chips having different thicknesses, and
the plurality of semiconductor chips are electrically connected to the redistribution layer of the connection member through wire posts having upper surfaces coplanar with an upper surface of the encapsulant and having different heights.

6. The fan-out semiconductor package of claim 5, wherein the respective wire posts include body portions disposed on the connection pads and having a first width and lead portions disposed on the body portions and having a second width smaller than the first width, and
the body portions of the respective wire posts have substantially the same height, and the lead portions of the respective wire posts have upper surfaces coplanar with the upper surface of the encapsulant and have different heights.

7. The fan-out semiconductor package of claim 1, wherein the connection member includes an insulating layer disposed on the encapsulant, and
the redistribution layer includes wiring patterns disposed on the insulating layer and connection vias penetrating through the insulating layer and connecting the wiring patterns and the wire posts to each other.

8. The fan-out semiconductor package of claim 1, wherein the plurality of insulating layers include a core insulating layer, one or more first build-up insulating layers disposed on a lower surface of the core insulating layer, and one or more second build-up insulating layers disposed on an upper surface of the core insulating layer, and
the core insulating layer has a thickness greater than that of each of the first and second build-up insulating layers.

9. The fan-out semiconductor package of claim 8, wherein the number of first build-up insulating layers and the number of second build-up insulating layers are the same as each other.

10. The fan-out semiconductor package of claim 8, wherein the recess portion penetrates through at least the core insulating layer and penetrates through at least one of the one or more second build-up insulating layers.

11. The fan-out semiconductor package of claim 8, wherein the plurality of connection via layers of the frame include first connection vias penetrating through the first build-up insulating layer and second connection vias penetrating through the second build-up insulating layer are tapered in opposite directions to each other.

12. The fan-out semiconductor package of claim 1, wherein a region of the stopper layer exposed by the recess portion has a thickness smaller than that of an edge region of the stopper layer that is not exposed.

13. The fan-out semiconductor package of claim 1, wherein walls of the recess portion are tapered.

14. The fan-out semiconductor package of claim 1, wherein the inactive surface of the semiconductor chip is attached to the stopper layer through an adhesive member.

15. The fan-out semiconductor package of claim 1, wherein the stopper layer is a metal layer,
at least one of the plurality of wiring layers includes a ground, and
the metal layer is electrically connected to the ground.

16. The fan-out semiconductor package of claim 1, wherein the stopper layer has a planar area greater than that of the inactive surface of the semiconductor chip.

17. The fan-out semiconductor package of claim 1, wherein the bottom surface of the recess portion has a planar area greater than that of the inactive surface of the semiconductor chip.

18. The fan-out semiconductor package of claim 1, further comprising:
a first passivation layer disposed on the connection member and having openings exposing at least portions of the redistribution layer;
underbump metal layers disposed in the openings of the first passivation layer and connected to at least portions of the exposed redistribution layer; and
electrical connection structures disposed on the first passivation layer and connected to the underbump metal layers.

19. The fan-out semiconductor package of claim 1, further comprising a second passivation layer disposed on a lower surface of the frame and having openings exposing at least portions of a lowermost wiring layer of the plurality of wiring layers.

20. A fan-out semiconductor package comprising:
a frame including a plurality of insulating layers and having a recess portion penetrating a portion of the frame, at least one of the plurality of insulating layers not penetrated through by the recess portion;
first semiconductor chip and second semiconductor chips and disposed in the recess portion, each of the first and second semiconductor chip having connection pads, an active surface on which the connection pads are disposed, and an inactive surface opposing the active surface and disposed on the at least one of the plurality of insulating layers not penetrated through by the recess portion;
an encapsulant covering at least portions of the first and second semiconductor chips and filling at least portions of the recess portion;
a connection member disposed on the frame and the active surfaces of the first and second semiconductor chip and including a redistribution layer;
first wire posts disposed between the connection pads of the first semiconductor chip and the redistribution layer, and electrically connecting the connection pads of the first semiconductor chip and the redistribution layer to each other; and
second wire posts disposed between the connection pads of the second semiconductor chip and the redistribution layer, and electrically connecting the connection pads of the second semiconductor chip and the redistribution layer to each other,
wherein each of the first wire posts includes a body portion disposed on one of the connection pads of the first semiconductor chip, and a lead portion having a width less than that of the body portion thereof and disposed between the body portion thereof and the redistribution layer,
each of the second wire posts includes a body portion disposed on one of the connection pads of the second semiconductor chip, and a lead portion having a width less than that of the body portion thereof and disposed between the body portion thereof and the redistribution layer, and
a thickness of the first semiconductor chip is greater than a thickness of the second semiconductor chip, and a height of the lead portion of each of the first wire posts is less than a height of the lead portion of each of the second wire posts.

21. The fan-out semiconductor package of claim 1, wherein at least one of the wiring layers are disposed on the level below the stopper layer.
